(19) United States
(12) Patent Application Publication
(10) Pub. No.: US 2012/0068280 A1
(43) Pub. Date: Mar. 22, 2012

(54) Magnetic Nano-Ring Device and Method of Fabrication

(75) Inventor: Alan S. Edelstein, Alexandria, VA (US)

(73) Assignee: U.S. Government as represented by the Secretary of the Army, Adelphi, MD (US)

(21) Appl. No.: 12/885,876

(22) Filed: Sep. 20, 2010

(51) Int. Cl. H01L 29/82; H01L 21/02

(52) U.S. Cl. 257/421; 438/3; 257/E29.323; 257/E21.002; 977/700

(57) ABSTRACT

A magnetic nano-ring device and method of fabrication includes providing a substrate; forming at least one nano-pillar on the substrate; depositing a plurality of electrodes on the substrate; depositing an anti-ferromagnetic layer on a first electrode of the plurality of electrodes; depositing a first ferromagnetic layer on the anti-ferromagnetic layer; depositing a tunnel barrier layer on the first ferromagnetic layer; depositing a second ferromagnetic layer on the tunnel barrier layer; planarizing the nano-pillars and the second ferromagnetic layer to form a co-planar nano-pillar and second ferromagnetic layer; depositing a second electrode on the co-planar nano-pillar and second ferromagnetic layer; and forming a nano-structure ring in a substantially cylindrical configuration.

### GOVERNMENT INTEREST

The embodiments herein may be manufactured, used, and/or licensed by or for the United States Government without the payment of royalties thereon.

### BACKGROUND OF THE INVENTION

1. Technical Field

The embodiments herein generally relate to magnetic nano-ring devices, and more particularly, to improved methods of fabricating magnetic nano-ring devices.

2. Description of the Related Art

Random access memory (RAM) is a ubiquitous component of modern digital architectures. RAM can be stand alone devices or can be integrated or embedded within devices that use the RAM such as microprocessors, microcontrollers, application specific integrated circuits (ASICs), system-on-chip (SoC), and other like devices as will be appreciated. RAM can be volatile or non-volatile. Volatile RAM loses its stored information whenever power is removed. Non-volatile RAM can maintain its memory contents even when power is removed from the memory. Although non-volatile RAM has advantages in the ability to maintain its contents without having power applied, conventional non-volatile RAM has slower read/write times than volatile RAM.

Magnetoresistive Random Access Memory (MRAM) is a non-volatile memory technology that has response (read/write) times comparable to volatile memory. In contrast to conventional RAM technologies, which store data as electric charges or current flows, MRAM uses magnetic elements. MRAM is based on the integration of silicon complementary metal-oxide-semiconductor (CMOS) with magnetic tunnel junction (MTJ) technology and is a major emerging technology that is highly competitive with existing semiconductor memories such as static random access memory (SRAM), dynamic random access memory (DRAM), and flash. Similarly, spin-transfer torque (STT) magnetization switching has received considerable interest due to its potential application for spintronic devices, such as STT-RAM, on a gigabit scale.

Both MRAM and STT-RAM have a MTJ element based on tunneling magneto-resistance (TMR) junctions wherein a stack of layers has a configuration in which two ferromagnetic layers are separated by a thin non-magnetic oxide layer. The MTJ element is typically formed between a bottom electrode such as a first conductive line and a top electrode, which is a second conductive line. A MTJ stack of layers may have configuration in which a seed layer, an anti-ferromagnetic (AFM) pinning layer, a ferromagnetic “pinned” layer, a thin tunnel barrier layer, a ferromagnetic “free” layer, and a capping layer are sequentially formed on a bottom electrode. The AFM layer holds the magnetic moment of the pinned layer in a fixed direction. The pinned layer has a magnetic moment that is fixed in the “y” direction, for example, by exchange coupling with the adjacent AFM layer that is also magnetized in the “y” direction. The free layer has a magnetic moment that is either parallel or anti-parallel to the magnetic moment in the pinned layer. The tunnel barrier layer is thin enough that a current through it can be established by quantum mechanical tunneling of conduction electrons. The direction of the magnetic moment of the free layer may change in response to external magnetic fields or to high-density spin polarized currents and it is the relative orientation of the magnetic moments between the free and pinned layers that determine the resistance of the tunneling junction. When a sense current is passed from the top electrode to the bottom electrode in a direction perpendicular to the MEI layers, a lower resistance is detected when the magnetization directions of the free and pinned layers are in a parallel state (“1” memory state) and a higher resistance is noted when they are in an anti-parallel state or “0” memory state.

### BRIEF SUMMARY OF THE INVENTION

In view of the foregoing, an embodiment herein provides a method of fabricating nano-ring devices, the method comprising providing a substrate; forming at least one nano-pillar on the substrate; depositing a plurality of electrodes on the substrate; depositing an anti-ferromagnetic layer on a first electrode of the plurality of electrodes; depositing a first ferromagnetic layer on the anti-ferromagnetic layer; depositing a tunnel barrier layer on the first ferromagnetic layer; depositing a second ferromagnetic layer on the tunnel barrier layer; planarizing the nano-pillars and the second ferromagnetic layer to form a co-planar nano-pillar and second ferromagnetic layer; depositing a second electrode on the co-planar nano-pillar and second ferromagnetic layer; and forming a nano-structure ring in a substantially cylindrical configuration.

Such a method may further comprise depositing a cap on top of each nano-pillar. In addition, such a method may further comprise depositing sidewall spacers around each nano-pillar. Moreover, the tunnel barrier layer may contact the substrate. Furthermore, depositing a tunnel barrier layer on the first ferromagnetic layer may comprise atomic layer deposition. Additionally, at least one of depositing an anti-ferromagnetic layer, depositing a first ferromagnetic layer, and depositing a second ferromagnetic layer vertically to minimize the deposition on a sidewall surface of the nano-pillar.

An embodiment herein also provides a method of fabricating nano-ring devices, the method comprising forming a stack comprising providing a substrate; forming at least one nano-pillar on the substrate; depositing a cap atop each nano-pillar; depositing a first electrode on the substrate; depositing an anti-ferromagnetic layer on the first electrode by depositing anti-ferromagnetic layer atoms vertically; depositing a first ferromagnetic layer on the anti-ferromagnetic layer by depositing first ferromagnetic layer atoms vertically; removing the cap; depositing a tunnel barrier layer on the first ferromagnetic layer comprising atomic layer deposition; depositing a second ferromagnetic layer on the tunnel barrier layer by depositing second ferromagnetic layer atoms vertically; planarizing the nano-pillars and the second ferromagnetic layer to form a co-planar nano-pillar and second ferromagnetic layer; depositing a second electrode on the co-planar nano-pillar and second ferromagnetic layer; and forming a nano-structure ring by removing excess material from the stack.

In such a method, the tunnel barrier layer may fill a space formed between the nano-pillar and the first electrode, the anti-ferromagnetic layer, and the first ferromagnetic layer. Such a method may further comprise depositing sidewall spacers around each nano-pillar. In addition, such a method may further comprise etching materials outside an edge of the sidewall spacers down to the first electrode; removing the sidewall spacers to create a space around the nano-pillar; and filling the space around the nano-pillar with silicon dioxide. Additionally, such a method may further comprise etching a sidewall of the nano-pillar.

In addition, an embodiment herein provides a magnetic nano-ring device comprising a substrate; a first electrode over the substrate; a plurality of nano-pillars affixed to the substrate, wherein each nano-pillar comprises a top surface and a sidewall surface; an anti-ferromagnetic layer covering exposed areas of the substrate and the top surface of each nano-pillar in the plurality of nano-pillars; a first ferromagnetic layer covering the anti-ferromagnetic layer; a tunnel barrier layer covering the first ferromagnetic layer and the sidewall surface of each nano-pillar in the plurality of nano-pillars; a second ferromagnetic layer covering the exposed areas of the tunnel barrier layer on the substrate and the top surface of each nano-pillar in the plurality of nano-pillars; and a second electrode over the second ferromagnetic layer.

In such a device, the nano-pillars may comprise insulating nano-pillars. Furthermore, the tunnel barrier layer may contact the substrate. In addition, the sidewall surface of the nano-pillar may comprise approximately a vertical sidewall surface. Moreover, the tunnel barrier layer covering the sidewall surface may prevent the second ferromagnetic layer from electrically shorting the first ferromagnetic layer. Additionally, the anti-ferromagnetic layer, the first ferromagnetic layer, and the second ferromagnetic layer may be positioned to expose the sidewall surface of each nano-pillar in the plurality of nano-pillars. Furthermore, the tunnel barrier layer may be deposited on the first ferromagnetic layer by atomic layer deposition. Alternatively, the tunnel barrier layer may be deposited on the first ferromagnetic layer by depositing the tunnel barrier layer at an angle while rotating the substrate. Moreover, the tunnel barrier layer covering the sidewall surface may prevent the second ferromagnetic layer from electrically shorting the first ferromagnetic layer. Additionally, the tunnel barrier layer may contact the substrate.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE SEVERAL VIEWS OF THE DRAWINGS

The embodiments herein will be better understood from the following detailed description with reference to the drawings, in which:

FIG. 1A illustrates a schematic diagram of a planar device with a clockwise magnetization direction according to an embodiment herein;

FIG. 1B illustrates a schematic diagram of a planar device with a counter-clockwise magnetization direction according to an embodiment herein;

FIG. 2A illustrates a schematic diagram of a substrate, with two nano-pillars, according to an embodiment herein;

FIG. 2B illustrates a schematic diagram of a substrate. with two nano-pillars and two caps according to an embodiment herein

FIG. 3A illustrates a schematic diagram of a first processing step of a nano-ring device according to a first embodiment herein;

FIG. 3B illustrates a schematic diagram of a second processing step of a nano-ring device according to a first embodiment herein;

FIG. 3C illustrates a schematic diagram of a third processing step of a nano-ring device according to a first embodiment herein;

FIG. 3D illustrates a schematic diagram of a fourth processing step of a nano-ring device according to a first embodiment herein;

FIG. 4A illustrates a schematic diagram of a first processing step of a nano-ring device according to a second embodiment herein;

FIG. 4B illustrates a schematic diagram of a second processing step of a nano-ring device according to a second embodiment herein;

FIG. 4C illustrates a schematic diagram of a third processing step of a nano-ring device according to a second embodiment herein;

FIG. 5A illustrates a schematic diagram of a first processing step of a nano-ring device according to a third embodiment herein;

FIG. 5B illustrates a schematic diagram of a second processing step of a nano-ring device according to a third embodiment herein;

FIG. 5C illustrates a schematic diagram of a third processing step of a nano-ring device according to a third embodiment herein;

FIG. 5D illustrates a schematic diagram of a fourth processing step of a nano-ring device according to a third embodiment herein;

FIG. 5E illustrates a schematic diagram of a fifth processing step of a nano-ring device according to a third embodiment herein;

FIG. 6A illustrates a schematic diagram of a first processing step of a nano-ring device according to a fourth embodiment herein;

FIG. 6B illustrates a schematic diagram of a second processing step of a nano-ring device according to a fourth embodiment herein;

FIG. 6C illustrates a schematic diagram of a third processing step of a nano-ring device according to a fourth embodiment herein;

FIG. 6D illustrates a schematic diagram of a fourth processing step of a nano-ring device according to a fourth embodiment herein; and

FIG. 7 illustrates a cross-sectional top view of a nano-ring device according to an embodiment herein.

### DETAILED DESCRIPTION OF THE INVENTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

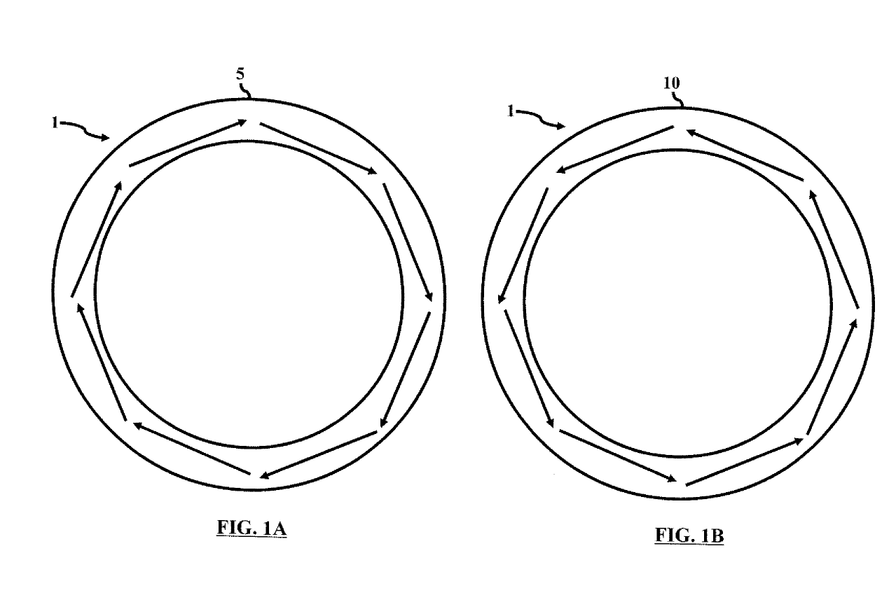

The embodiments herein provide devices and processes of fabricating ring-shaped devices; i.e., circular devices with a concentric hole. For example, the embodiments herein use nano-pillars as templates and a process that deposits some material to cover the sidewalls of the nano-pillars. Embodiments herein benefit from the structure and processes described below, for example, by protecting the devices from shorting between layers of the device. Referring now to the drawings, and more particularly to FIGS. 1A through 7, where similar reference characters denote corresponding features consistently throughout the figures, there are shown preferred embodiments.

As described above, there is considerable interest in magnetic storage devices that include giant magnetic resistance devices and magnetic tunnel junctions especially in the form of rings. Conventional systems, however, have been unable to reliably fabricate planar devices in the form of nano-rings. For example, conventionally fabricated planar devices (e.g., planar nano-rings), which may include ferromagnetic layers, have a risk of creating short circuits between the different ferromagnetic layers that comprise the planar device. The embodiments described herein offer several improvements over conventional devices—for example, the embodiments herein minimize the risk of creating shorts between ferromagnetic layers and does not fabricate the individual devices in a serial fashion thus reducing the fabrication time.

FIGS. 1A and 113 illustrate schematic diagrams of planar device 1 in a closed ring geometry. While not shown, planar device 1 has active ferromagnetic films (or layers, as described below) and forms a closed ring. The geometry shown in FIGS. 1A and 1B can have advantages over conventional devices in that planar device 1 may offer a small geometry (as described below) and thereby occupies less valuable area and does not have the domain walls (e.g., separating magnetic domains) experienced by larger geometries. Further, less energy is required to change the magnetization because there is no shape anisotropy. As shown in FIGS. 1A and 1B, planar device 1 has two possible magnetization geometries (e.g., clockwise geometry 5 and counterclockwise geometry 10).

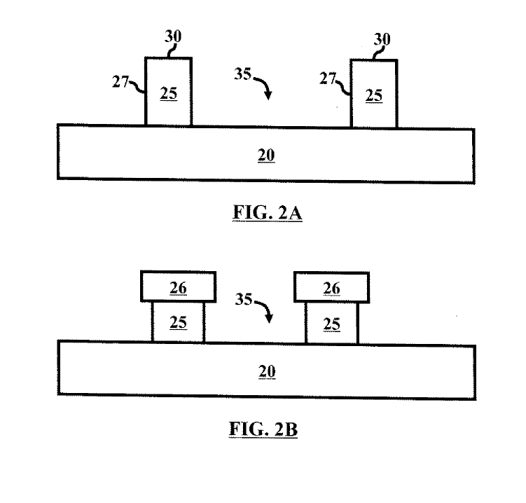

The embodiments shown in FIGS. 2A through 6 illustrate various steps used to fabricate planar device 1. FIG. 2A, with reference to FIG. 1, illustrates a substrate 20 and a plurality of nano-pillars 25 affixed thereto. Nano-pillars 25 further include a diameter 30 and each nano-pillar 25 is separated by spacing 35. While not shown in the embodiment of FIG. 2A, each nano-pillar 25 has roughly the same diameter 30 to create a uniform array of nano-pillars 25 of spacing 35. For example, in one embodiment herein, each nano-pillar 25 has a diameter 30 approximately equal to 30 nanometers and spacing 35 (i.e., the space between individual nano-pillars 25) is approximately equal to 50 nanometers. In addition, the embodiment shown in FIG. 2A also includes nano-pillars 25 with nearly vertical sidewalls 27. While not shown, nano-pillars 25 of the embodiment shown in FIG. 2A are insulating pillars (e.g., oxide nano-pillars).

In addition, while not shown in the embodiment of FIG. 2A, spacer pillars may also be deposited on the edge of substrate 20 (e.g., on the edge of a wafer, where the wafer includes substrate 20). In such embodiment, these spacer pillars prevent subsequent masks from touching nano-pillars 25. Furthermore, although not shown, the embodiment of FIG. 2A uses photolithographic techniques to mask, standard deposition techniques to deposit material, and etching and lift off techniques to remove excess material from substrate 20.

An alternative embodiment is shown in FIG. 2B where each of the nano-pillars 25 may also include a cap 26. In the embodiment shown, caps 26 are used to minimize the possibility of shorting between the ferromagnetic layers (as described in further detail below).

The following is an example how the structure in FIG. 2B can be fabricated. A layer of silicon dioxide, which becomes the nano-pillars 25 followed by a layer of silicon, which becomes the cap 26, is deposited or grown on substrate 20. Electron beam lithography can be used define the diameter of the nano-pillars 25 and silicon caps 26. Reactive ion etching can be used to remove the unwanted silicon and leave the silicon caps 26. Suitable etching with hydrofluoric (HF) acid can be used to remove the unwanted silicon dioxide and create the pillars. Controlling the conditions of the HF step allows undercutting the silicon caps 26 as shown in FIG. 2B.

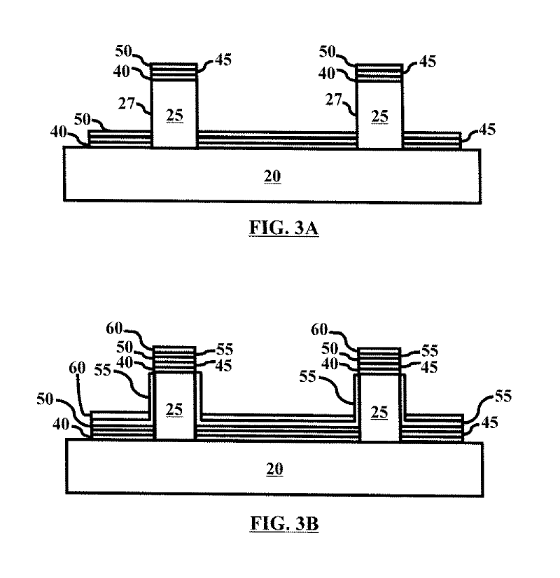

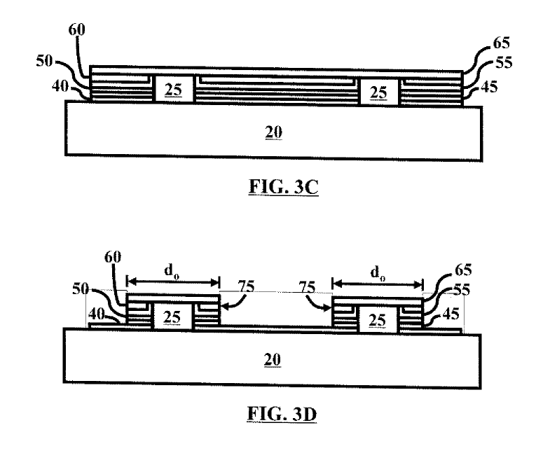

FIGS. 3A through 7B, with reference to FIGS. 2A and 2B, illustrate various embodiments herein. According to FIGS. 3A through 3D, a first embodiment is illustrated. In the first embodiment, a lithography plus vertical deposition process is provided. Here, the process is shown to continue after the configuration of FIG. 2A. A sequential layering is applied to substrate 20 and nano-pillars 25 including a conducting, metallic layer that constitutes a first electrode 40, followed by an anti-ferromagnetic pinning layer 45, and then a first ferromagnetic layer 50.

Next, as shown in FIG. 3B, a tunnel barrier layer 55, and a second ferromagnetic layer 60 are deposited. The tunnel barrier layer 55 may be deposited using either atomic layer deposition (to cover all exposed surfaces) or the tunnel barrier layer 55 may be deposited at an angle while rotating substrate 20 (e.g., rotating a wafer that includes substrate 20). Possible tunnel barrier materials include crystalline magnesium oxide (MgO). In so doing, in the embodiment of FIG. 3B, the tunnel barrier layer 55 covers the sidewalls 27 of nano-pillars 25. Those of ordinary skill in the art will recognize that other embodiments may include alternative and/or additional materials in tunnel barrier layer 55 and may include alternative and/or additional deposition techniques to cover sidewalls 27 of nano-pillars 25. The thickness of the tunnel barrier layer 55 is controlled and kept sufficiently thin (i.e., approximately 1 nanometer) to optimize the electron tunneling.

While not explicitly, shown, the deposition in the embodiments of FIGS. 3A and 3B is made with the atoms of the corresponding deposited material (e.g., layers 40, 45, 50, 60) coming down normal to the surface of the substrate 20 thereby minimizing the deposition of material on sidewalls 27 of nano-pillars 25. The tunnel barrier layer 55 deposition should be made so the sidewalls 27 of the nano-pillars 25 are covered. Consequently, the embodiments of FIGS. 3A and 33 minimize deposited metallic material on sidewalls 27.

Next, as shown in FIG. 3C, a planarization step occurs down to the second ferromagnetic layer 60 on the portion of the stacked layers on top of substrate 20 with the nano-pillars 25 being planarized as well so that the top of layer 60 is co-planar with the top of nano-pillars 25. Thereafter, a conducting, metallic layer that constitutes a second electrode 65 is deposited. Finally, as shown in FIG. 3D, the nano-ring structures 75, having diameter dₒ, are formed by performing a photolithographic technique and etching to remove the excess material down to the first electrode 40.

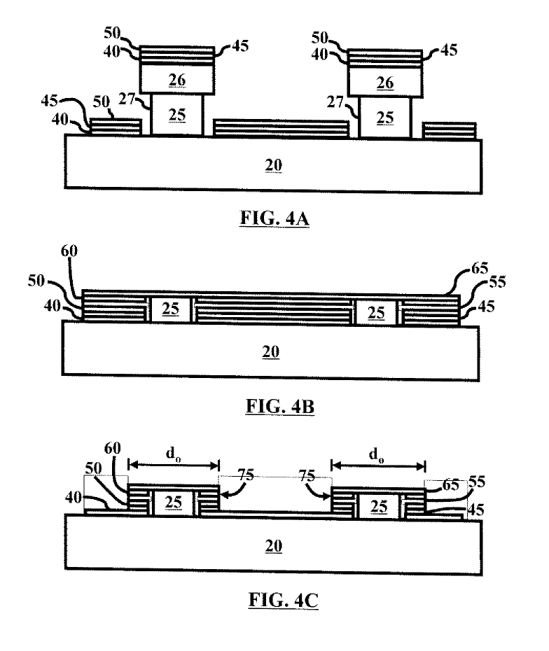

According to FIGS. 4A through 4C, a second embodiment is illustrated. In the second embodiment, a lithography plus cap process is provided. Here, the process is shown to continue after the alternative configuration of FIG. 2B. A sequential layering is applied to substrate 20 and caps 26 including the first electrode 40, followed by the anti-ferromagnetic pinning layer 45, and then the first ferromagnetic layer 50.

In this embodiment, the first electrode 40, anti-ferromagnetic pinning layer 45, and first ferromagnetic layer 50 are deposited with the atoms coming down vertically to minimize the number of the atoms being deposited under the cap 26 near the sidewalls 27 of the nano-pillars 25. Then, the caps 26 and overlying material are removed by etching. Next, the tunnel barrier layer 55 is deposited. The material of the tunnel barrier layer 55 fills the space between the three-layer stack of the first electrode 40, anti-ferromagnetic pinning layer 45, and first ferromagnetic layer 50 and the sidewalls 27 of the nano-pillars 25. Thereafter, the second ferromagnetic layer 60 is deposited on the tunnel barrier layer 55. These steps minimize the likelihood of shorting between the two ferromagnetic layers 50, 60. After a planarization step that removes the nano-pillar 25 down to the level of the top of the second ferromagnetic layer 60, the second electrode 65 is deposited with the resulting structure shown in FIG. 4B. Finally, as shown in FIG. 4C, the nano-ring structures 75, having diameter dₒ, are formed by performing a photolithographic technique and etching to remove the excess material down to the first electrode 40.

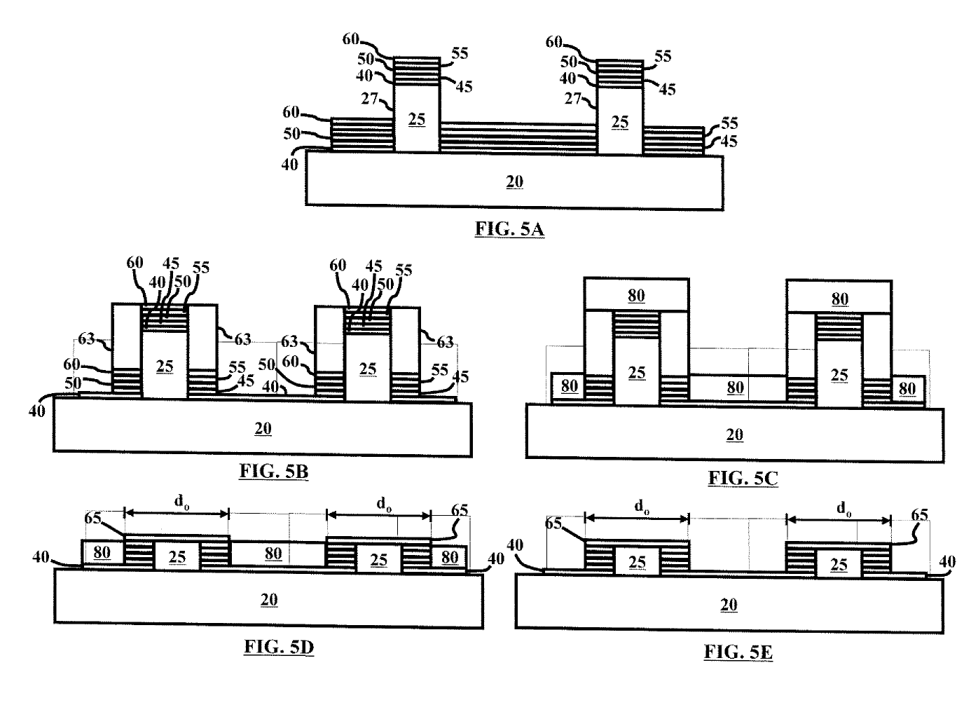

According to FIGS. 5A through 5E, a third embodiment is illustrated. In the third embodiment, a sidewall spacer plus vertical deposition process is provided. Here, the process is shown to continue after the configuration of FIG. 2A. A sequential layering is applied to substrate 20 and nano-pillars 25 including a first electrode 40, followed by an anti-ferromagnetic pinning layer 45, a first ferromagnetic layer 50, a tunnel barrier layer 55, and a second ferromagnetic layer 60 as illustrated in FIG. 5A. The metallic layers are deposited vertically to minimize covering the sidewalls 27 of the nano-pillars 25 and minimize creating shorting.

One can then cover the sidewalls 27 of the nano-pillars 25 with a sidewall spacer 63 and then perform an etching process as shown in FIG. 5B that removes material down to the top of the first electrode 40. Now the space that has been etched is filled with SiO₂ 80 as shown in FIG. 5C. Upon completion of this step, the surface is planarized by mechanical polishing down to the top of the second ferromagnetic layer 60. At this point lithography is performed and the second electrode 65 is deposited as shown in FIG. 5D. The nano-ring structures 75, having diameter dₒ, are defined by the thickness of the sidewall spacer 63. The last step shown in FIG. 5E is to remove the SiO₂ 80 by etching down to the first electrode 40.

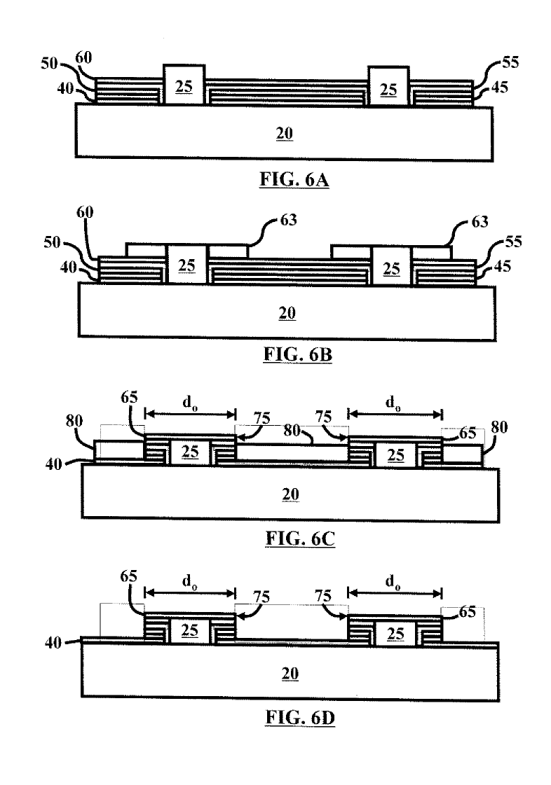

According to FIGS. 6A through 6D, a fourth embodiment is illustrated. In the fourth embodiment, a sidewall spacer plus cap process is provided. Here, the process is shown to continue after the configuration of FIG. 4A with a sequential layering having been applied to substrate 20 and caps 26 including the first electrode 40, followed by the anti-ferromagnetic pinning layer 45, and then the first ferromagnetic layer 50.

Then, the caps 26 and overlying material are removed. Next, the tunnel barrier layer 55 is deposited along the sidewalls 27 of the nano-pillars 25 all the way down to the substrate 20. Thereafter, the second ferromagnetic layer 60 is deposited on the tunnel barrier layer 55. These steps minimize the likelihood of shorting between the two ferromagnetic layers 50, 60. The resulting structure is shown in FIG. 6A. After this, as illustrated in FIG. 6B, sidewall spacer material 63 is deposited to define the thickness of the ensuing nano-rings. Next, the stack of films 40, 45, 50, 55, and 60 are etched. Then, the space is again filled with silicon dioxide 80. After a planarization step in which the planarization is performed to the top of the second ferromagnetic layer 60, the second electrode 65 is deposited with the resulting structure shown in FIG. 6C with the nano-ring structures 75 having diameter dₒ. The last step shown in FIG. 6D is to remove the SiO₂ 80 by etching down to the first electrode 40.

A fifth embodiment, not specifically shown, is to start with the configuration shown in FIG. 3A. Next, one can etch the sidewalls 27 of the nano-pillars 25 after depositing the first ferromagnetic layer 50 to create a space that will be filled when the tunnel barrier layer 55 is deposited. This prevents shorting. From the above, one can easily see other variations of this embodiment.

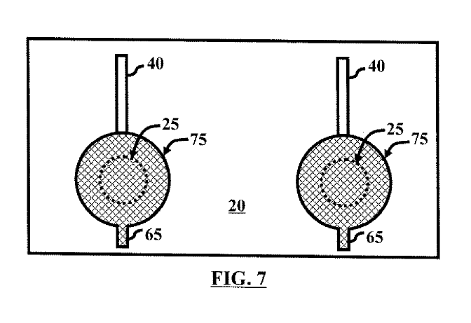

FIG. 7, with reference to FIGS. 1A through 6D, illustrates cross-sectional top view of the substrate 20 with nano-ring structure 75, nano-pillar 25, first electrode 40, and second electrode 65. It is noted that, in an alternative embodiment, the first electrode 40 may be deposited and structurally defined prior to the creation of nano-pillars 25.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

1-11. (canceled)

12. A magnetic nano-ring device comprising:
a substrate,
a first electrode over said substrate having an approximate ring shaped structure;
a plurality of cylindrical nana-pillars affixed to said substrate, wherein each nana-pillar comprises a top surface and a sidewall surface;
an anti-ferromagnetic layer covering exposed areas of said substrate and a circular layer on the top surface of each nano-pillar in said plurality of nano-pillars;
a first ferromagnetic layer a substantially circular geometry covering said antiferromagnetic layer;
a tunnel barrier layer having an approximate ring shape covering said first ferromagnetic layer and the sidewall surface of each nano-pillar in said plurality at nano-pillars;
a second ferromagnetic layer having an approximate ring shape covering said exposed areas of said tunnel barrier layer on said substrate and the top surface of each nano-pillar in said plurality of nano-pillars; and
a second electrode having an approximate ring shape over said second ferromagnetic layer.

13. The device of claim 12, wherein said nano-pillars comprise insulating nano-pillars having an approximate ring shape.

14. The device of claim 12, wherein said tunnel barrier layer of insulating nature that has an approximate ring shape and contacts said substrate.

15. The device of claim 12, wherein said sidewall surface of said nano-pillar comprises approximately a vertical sidewall surface having an approximate ring shape.

16. (canceled)

17. (canceled)

18. The device of claim 12, wherein said tunnel barrier layer is deposited on said first ferromagnetic layer by atomic layer deposition to form an approximate ring shape.

19. (canceled)

20. (canceled)
